(19) United States
(12) Patent Application Publication
(10) Pub. No.: US 2026/0189238 A1
(43) Pub. Date: Jul. 2, 2026

(54) ADAPTIVE PHASE LOCK LOOP WITH FAST LOCK FOR SUPPLY VOLTAGE DROOP

(71) Applicant: Microsoft Technology Licensing, LLC, Redmond, WA (US)

(72) Inventors: Ping LU, Cary, NC (US); Eric Douglas GROEN, Ankeny, IA (US)

(73) Assignee: Microsoft Technology Licensing, LLC, Redmond, WA (US)

(21) Appl. No.: 19/002,841

(22) Filed: Dec. 27, 2024

(51) Int. Cl. H03L 7/099; H03L 7/093

(52) U.S. Cl. CPC H03L 7/0992; H03L 7/093

(57) ABSTRACT

A phase-locked loop comprises circuits for detecting a voltage droop of a supply voltage and quickly reducing the frequency of an output clock as supplied to a corresponding subsystem such as in an integrated circuit. Reducing the frequency of the output clock to the corresponding subsystem during the voltage droop compensates for and mitigates the effects of the voltage droop, allowing the corresponding subsystem to continue to function properly during the voltage droop at a lower output clock frequency. The phase-locked loop as disclosed includes the ability for fast frequency hopping of the output clock during transitions between a droop mode and a normal mode. The phase-locked loop may further include a frequency overshoot remover that removes frequency overshoot during the transitions.

### BACKGROUND

In very large-scale integrated circuit (VLSI) chips, a variety of different subsystems are typically included to form an overall system. These subsystems rely on receiving both a supply voltage and ground to operate properly, in addition to a clock signal to operate at a desired speed for performing their designated function. Across the VLSI chip, there may be complex and lengthy supply voltage and ground routings that cause severe voltage drops to subsystems particularly at the far end of the routings from the supply voltage. Subsystems performing intensive digital functions such as graphical processing units (GPUs) and artificial intelligence (AI) may induce significant switch current spikes at clock trigger moments, resulting in a voltage droop to the supply voltage. Voltage droops are often transient, where the supply voltage may vary significantly and unpredictably in a short amount of time. The effect on a subsystem from supply voltage droops may include a slow-down in MOS (metal oxide semiconductor) transistor operation that may cause timing issues within the subsystem and between other subsystems, as well as performance and reliability issues, and even fault conditions within the VLSI chip.

Phase-locked loops (PLLs) are a popular design choice as clock generators in VLSI chips and are often used in multiple locations of a clock distribution network across a VLSI chip for supplying clock signals to the various modules and subsystems. Digital phase-locked loops (DPLLs) are an all-digital variant of the analog PLLs that are easier to fabricate as part of a VLSI chip and allow for a small feature size, less dependency on device fabrication processes, and easier duplication into new chip designs.

Techniques to compensate for voltage droops in the supply voltage are directed either to regulating the supply voltage in a way to reduce the voltage droop, or to dynamically reducing a frequency of a system clock signal when the voltage droop is detected. In the latter approach, the frequency of the system clock signal is ideally reduced as quickly as possible in response to detecting the voltage droop and similarly restoring the frequency of the clock signal when the supply voltage returns to normal. Delays in providing the system clock at the appropriate higher or lower frequency can adversely affect the performance of the subsystem receiving the system clock signal.

In general, it would be advantageous to provide techniques and circuitry for quickly reducing the clock signal frequency in response to detection of the voltage droop in the supply voltage and then quickly restoring the clock signal frequency in response to the supply voltage returning to a normal value.

### SUMMARY

In one general aspect, the present invention relates to a phase-locked loop that comprises a phase detector that receives a reference clock and a feedback signal, the phase detector generating a delta value indicating a time difference between the reference clock and the feedback signal, an output clock generator that receives the delta value, generates a control signal based on the delta value, and generates an output clock at a target frequency based on the control signal, a divider circuit that receives the output clock and generates the feedback signal based on the output clock and a divider ratio, a gain adjustment circuit that provides an optimized injection frequency control to the control signal of the output clock generator, and a comparator that compares a supply voltage against a threshold voltage to determine a mode including a droop mode when the supply voltage is less than the threshold voltage and a normal mode when the supply voltage is greater than the threshold voltage, wherein during the droop mode, a reduction factor is deducted from the divider ratio that reduces the target frequency of the output clock.

In another general aspect, the present invention relates to a method of generating an output clock in a phase-locked loop, comprising receiving in a phase detector a reference clock and a feedback signal, generating by the phase detector a delta value indicating a time difference between the reference clock and the feedback signal, receiving in a divider circuit the output clock, generating a feedback signal by the divider circuit based on the output clock and a divider ratio, receiving, in an output clock generator, the delta value, generating a control signal by the output clock generator based on the delta value, generating the output clock based on the control signal, providing, by a gain adjustment circuit, an optimized injection frequency control to the output clock generator, comparing by a comparator a supply voltage against a threshold voltage, determining by the comparator a droop mode when the supply voltage is less than the threshold voltage and a normal mode when the supply voltage is greater than the threshold voltage, and during the droop mode, reducing a target frequency of the output clock by deducting a reduction factor from the divider ratio in the divider circuit.

In a further general aspect, the present invention relates to An integrated circuit, comprising a plurality of subsystems coupled to receive a supply voltage and a plurality of phase-locked loops, the plurality of phase-locked loops coupled to receive the supply voltage and a reference clock, and further coupled to a corresponding subsystem to provide an output clock to the corresponding subsystem The plurality of phase-locked loops comprise a phase detector that receives the reference clock and a feedback signal, the phase detector generating a delta value indicating a time difference between the reference clock and the feedback signal, a divider circuit that receives the output clock and generates the feedback signal based on the output clock and a divider ratio. an output clock generator that receives the delta value, generates a control signal based on the delta value, and generates the output clock at a target frequency based on the control signal, a gain adjustment circuit that provides an optimized injection frequency control to the output clock generator; and a comparator that compares the supply voltage against a threshold voltage and determines a droop mode when the supply voltage is less than the threshold voltage and a normal mode when the supply voltage is greater than the threshold voltage, wherein during droop mode, a reduction factor is deducted from the divider ratio to reduce the target frequency of the output clock.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject of this disclosure.

### BRIEF DESCRIPTION OF THE DRAWINGS

The drawing figures depict one or more implementations in accord with the present teachings, by way of example only, not by way of limitation. In the figures, like reference numerals refer to the same or similar elements. Furthermore, it should be understood that the drawings are not necessarily to scale.

FIG. 1 is a schematic diagram of a phase-locked loop according to the disclosure.

FIG. 2 is a schematic diagram of the phase-locked loop of FIG. 1 further including a frequency overshoot remover.

FIG. 3 is an illustration showing example output clock frequency of the phase-locked loop.

FIG. 4 is a schematic diagram showing additional details of a gain adjustment circuit of the phase-locked loop.

FIG. 5 is a schematic diagram of the phase-locked loop of FIG. 1 further including a multiple droop mode capability.

FIG. 6 is a block diagram of an exemplary integrated circuit implementation of the phase-locked loop.

FIG. 7 is a flow chart of an example process for generating for generating an output clock according to the techniques disclosed herein.

### DETAILED DESCRIPTION

Exemplary aspects disclosed herein include phase-locked loops that include circuits for detecting a voltage droop of a supply voltage and quickly reducing an output clock frequency in response. Voltage droop in an integrated circuit occurs particularly when various subsystems that tend to draw a significant amount of current to perform their designated functions, for example a graphics processing unit (GPU) or an artificial intelligence (AI) processor core, are activated. The current draw, and the resulting voltage droop, tend to change rapidly and in a transient fashion. It is desirable that the phase-locked loop, upon detecting the voltage droop, will respond by rapidly reducing the clock frequency to the corresponding subsystem. The effect of voltage droop on the corresponding subsystem often induces slower MOS (metal oxide semiconductor) transistor operation, resulting in timing issues and potential failure of the corresponding subsystem to operate properly. Reducing the clock frequency to the subsystem is a way to compensate for and mitigate the effects of the voltage droop, allowing the corresponding subsystem to continue to function properly during a voltage droop at a lower clock frequency. The phase-locked loop as disclosed includes the ability for fast frequency hopping of the output clock during transitions between the normal clock frequency and a reduced clock frequency during a voltage droop.

Further exemplary aspects include a frequency overshoot remover circuit that introduces a delay into a slow injection path of the phase-locked loop to ensure that there is no significant overshoot by the output clock during a transition from the reduced clock frequency to the normal clock frequency. A phase detector receives a reference clock and a feedback signal and provides a delta value that is a relative time difference between the reference clock and the feedback signal, to an output clock generator that generates the output clock. A divider circuit with a selected divider ratio receives the output clock and generates the feedback signal to form a feedback loop. The feedback loop further includes a gain adjustment circuit that receives the delta value and provides an optimized injection frequency control to the output clock generator. The feedback loop operates according to two-point injection. A slow injection path is via the divider circuit. The fast injection path is via the gain adjustment circuit that is programmed to provide an optimized injection frequency control in the output clock generator to allow for the desired speed of transitions between the normal clock frequency and reduced clock frequency.

Further exemplary aspects include the phase-locked loop configured for two-point injection. In this regard, the output clock generator includes a first adder. A second adder is coupled to the divider circuit. The locations of the first adder and the second adder are chosen to provide an all-pass transfer function for an injected signal. The injection from the first adder in the output clock has only a digitally controlled oscillator in the feedforward path, resulting in a high-pass transfer function that boosts higher frequency input above a first “corner” frequency. The second adder to the divider has a low-pass transfer function that filters out high-frequency inputs above a second “corner” frequency. By adding the injected signal to the feedback signal in the second adder and also adding a weighted version of the injected signal via the gain adjustment circuit to the control signal in the first adder, the combination of the high-pass and low-pass filtering of the loop produces an all-pass transfer function of the first corner frequency and the second corner frequency that are aligned at a same frequency. The result is a capability of the phase-locked loop to provide very rapid changes in frequency of the output clock to achieve the desired speed of transitions between the normal clock frequency and reduced clock frequency.

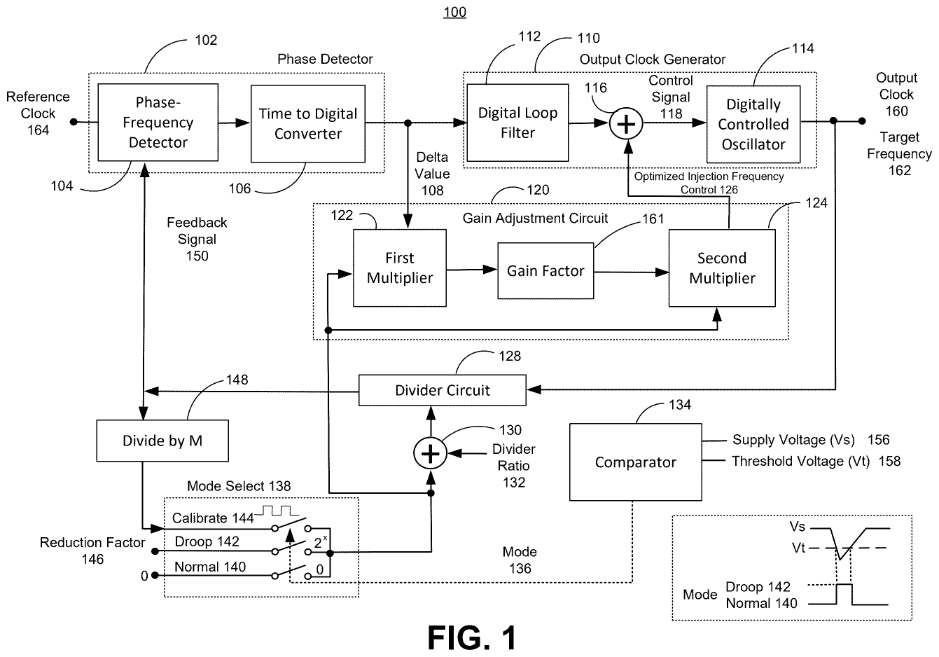

FIG. 1 is a schematic diagram of a phase-locked loop 100 that includes a phase detector 102 coupled to receive a reference clock 164 and a feedback signal 150 from a divider circuit 128. The reference clock 164 is received from an external source, such as a crystal-controlled oscillator that has a reference clock frequency that is relatively stable over temperature and voltage. The feedback signal 150 during normal operation will have a frequency equal to the frequency of the reference clock 164. The phase detector 102 further includes a phase-frequency detector 104 coupled to receive the reference clock 164 and the feedback signal 150, and a time-to-digital converter 106 coupled to the phase-frequency detector 104 to produce a delta value 108 which represents the time difference between the reference clock 164 and the feedback signal 150. The delta value 108 is quantified digitally as a binary number generated by the time-to-digital converter 106.

An output clock generator 110 is coupled to the phase detector 102 to receive the delta value 108 and further coupled to a gain adjustment circuit 120 to receive an optimized injection frequency control 126. The output clock generator 110 generates an output clock 160 at a target frequency 162 responsive to the delta value 108. The output clock generator 110 further includes a digital loop filter 112 coupled to receive the delta value 108. An adder 116 is coupled to receive the output of the digital loop filter 112 as a filtered delta value and the optimized injection frequency control 126 to produce a control signal 118. The output clock generator 110 further includes a digitally controlled oscillator (DCO) 114 that is coupled to the adder 116 to receive the control signal 118 and generate the output clock 160 at the target frequency 162 based on the control signal 118.

A gain adjustment circuit 120 is coupled to the phase detector 102 to receive the delta value 108 and is further coupled to a mode select block 138 to receive an error value that is one of a ‘0’ during a normal mode 140 corresponding to no injection into the adder 130, a reduction factor 146 during a droop mode 142 into the adder 130, and a low-frequency calibrate signal 145 during a calibration mode 144 into the adder 130, the adder 130 further coupled to the divider circuit 128. The gain adjustment circuit 120 further includes a first multiplier 122, a second multiplier 124, and a gain factor block 161. The first multiplier 122 is coupled to the second multiplier 124 via the gain factor block 161, and the first multiplier 122 and the second multiplier 124 both coupled to receive the error value from the mode select block 138.

During the calibration mode 144, which may be externally selected at desired intervals, a divide-by-M block 148 is activated to produce the calibrate signal 145. The gain factor block 161 that stores a gain factor that then is used in conjunction with the first multiplier 122 and the second multiplier 124 to obtain the optimized injection frequency control 126 to adjust the high-pass injection gain at the output of the gain factor block 161 to a nominal value that provides an all-pass injection of the phase-locked loop 100. Following the completion of the calibration mode 144, the optimized injection frequency control 126 is supplied to the output clock generator 110 by the gain adjustment circuit 120 to adjust the gain of the output clock generator 110 to the nominal gain to achieve the desired loop bandwidth.

The divider circuit 128 is coupled to an adder 130 to receive a divider ratio 132 that determines the target frequency 162. The divider circuit 128 can be implemented using a ‘multi-modulus divider’ (MMD). For example, the divider ratio set to 40 with a reference clock 164 at the reference frequency of 150 MHz would yield a target frequency 162 to be 6 GHz. The adder 130 is further coupled to the mode select block 138 which in turn is coupled to a comparator 134 to receive a mode 136.

The comparator 134 operates to compare the supply voltage 156 to a threshold voltage 158 to determine the mode 136. When the supply voltage 156 is greater than the threshold voltage 158, the comparator 134 determines the state of the mode 136 to be the normal mode 140. When the supply voltage 156 is less than the threshold voltage 158, the comparator 134 determines the state of the mode 136 to be the droop mode 142. The change in state of the mode 136 between the normal mode 140 and the droop mode 142 are the transitions.

The mode select block 138 closes one of three switches, responsive the state of the mode 136. In normal mode, the mode select block 138 selects a ‘0’ to be provided to the adder 130, resulting in the divider circuit continuing to operate according to the divider ratio 132. In droop mode, the mode select block 138 selects a reduction factor 146 to be provided to the adder 130. The value of the reduction factor 146, which is deducted from the divider ratio 132, is chosen to provide the output clock 160 with a reduced clock frequency that is chosen according to the requirements of the corresponding subsystem that receives the output clock 160 in order to maintain reliable operation during the supply voltage droop. For example, with a divider ratio 132 of 40 and the reference clock 164 with a reference frequency of 150 MHz, and a reduction factor of 2, the target frequency 162 transitions from 6 Ghz during the normal mode 140 to 5.7 GHz during the droop mode 142. The value of the optimized injection frequency control 126 is chosen to provide the desired loop bandwidth to support a sufficiently rapid frequency change of the output clock 160 to respond to the change in state of the mode 136.

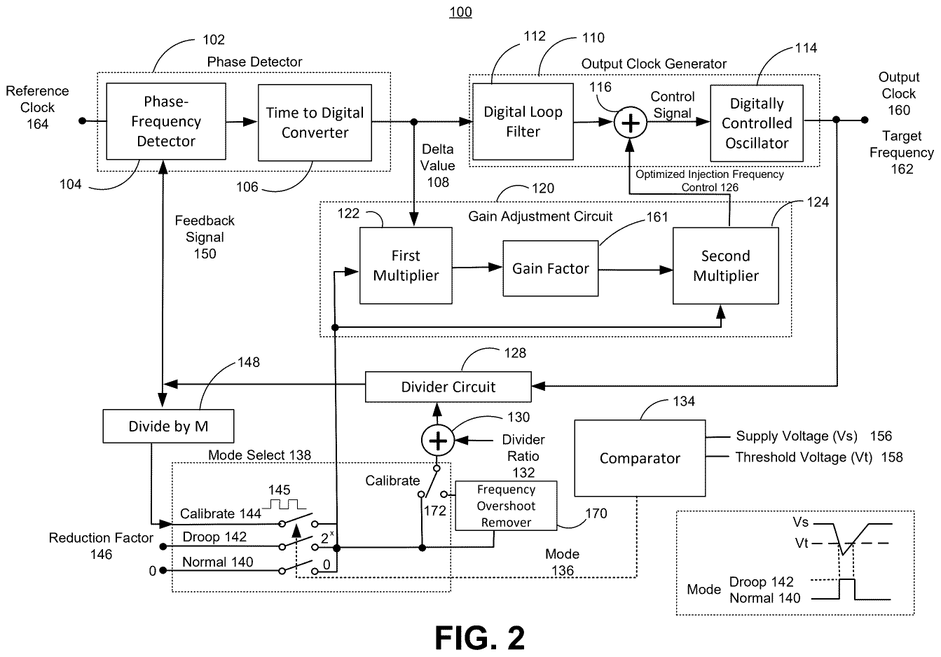

FIG. 2 is a schematic diagram of the phase-locked loop of FIG. 1 further including a frequency overshoot remover 170 that is coupled to a switch 172 in the mode select block 138. The switch 172 is further coupled to adder 130. All other elements of FIG. 2 are the same as those in FIG. 1 and, for the sake of brevity, will not be described further. During the calibration mode 144, the switch 172 couples the adder 130 to the divide-by-M block 148 to operate in the same manner as FIG. 1. During the normal mode 140 and the droop mode 142, the switch 172 couples the frequency overshoot remover 170 to the adder 130, allowing the frequency overshoot remover 170 to operate by inserting a desired number of cycles of delay before the reduction factor 146 is deducted from the divider ratio 132 applied the divider circuit 128. In an example implementation, the delay is 1 cycle of the reference clock 164 which when inserted into the divider injection path represented by the adder 130 operates to mitigate the frequency overshoot when the phase-locked loop 100 transitions from the droop mode 142 back to the normal mode 140.

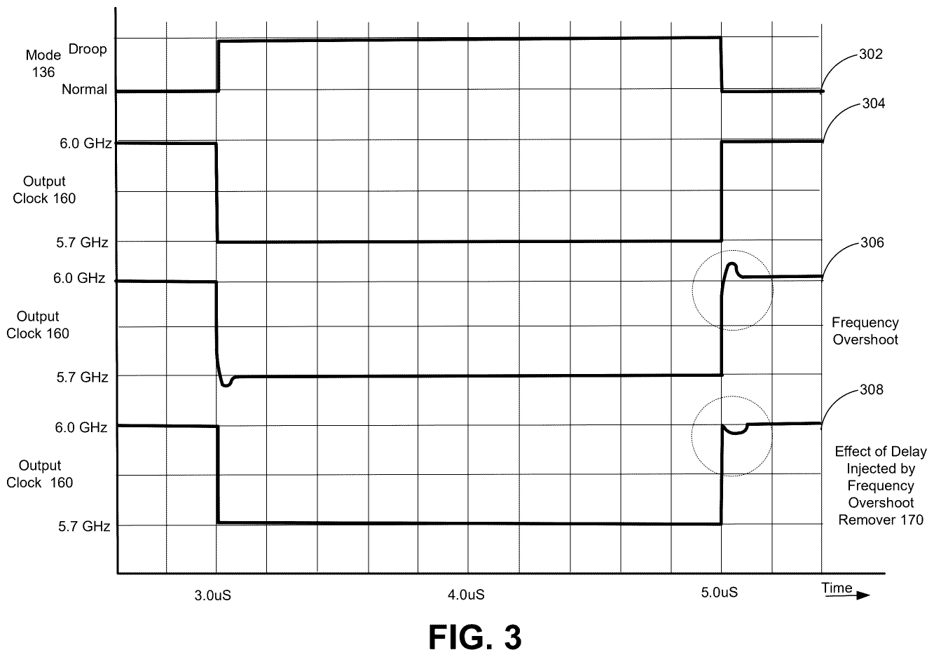

FIG. 3 is an illustration showing the output clocks 160 of the phase-locked loop 100 in an example implementation responsive to the transitions between the droop mode 142 and the normal mode 140. The horizontal scale is in time, with a first transition from the normal mode 140 to the droop mode 142 occurring at 3 microseconds (3 μS) and the second transition from the droop mode 142 back to the normal mode 140 occurring at 5 microseconds (5 μS). Trace 302 illustrates the state of mode 136 during the first transition at 3 μS and the second transition 5 μS as the phase-locked loop 100 detects the voltage droop in the supply voltage 156 as it drops below the threshold voltage 158. Trace 304 illustrates the output clock 160 operating at a target frequency 162 of 6 GHz during the normal mode 140, switching to a reduced clock frequency of 5.7 GHz at the first transition at 3 μS for the duration of the droop mode 142, and returning to 6 GHz at the second transition at 5 μS. In this example, the divider ratio set to 40 with a reference clock 164 at the reference frequency of 150 MHz would yield a target frequency 162 to be 6 GHz during the normal mode 140. During the droop mode 142, the reduction factor 146, which is deducted from the divider ratio 132, is chosen to provide the output clock 160 with a reduced frequency of the output clock 160 that is chosen according to the requirements of the corresponding subsystem being provided with the output clock 160 in order to maintain reliable operation during the supply voltage droop. In this example, with a divider ratio 132 of 40 and the reference clock 164 with a reference frequency of 150 MHz, and a reduction factor of 2, the target frequency 162 transitions from 6Ghz during the normal mode 140 to 5.7 GHz during the droop mode 142.

Trace 306 illustrates the frequency behavior of the output clock 160 when the output clock generator 110 of FIG. 1 contains a ripple pole, which is a physical effect of the phase-locked loop 100 as it achieves re-lock during the first transition at 3 μS and the second transition 5 μS. The ripple pole and resulting frequency overshoot (circled in the trace 306) are not desirable and may be mitigated using the frequency overshoot remover 170 that operates by inserting a desired number of cycles of delay before the reduction factor 146 is deducted from the divider ratio 132 applied the divider circuit 128. In the example implementation, the delay is 1 cycle of the reference clock 164 which when inserted into the divider injection path represented by the adder 130 that operates to mitigate the frequency overshoot when the phase-locked loop 100 transitions from the droop mode 142 back to the normal mode 140. Trace 308 shows the frequency overshoot to be substantially mitigated at the second transition at 5 μS.

The traces 304, 306, and 308 collectively illustrate the desirable capability of the phase-locked loop 100 to very rapidly respond to transitions in the state of the mode 136 between the normal mode 140 and the droop mode 142 with the output clock 160 shifting the target frequency 162 rapidly to the reduced clock frequency that is chosen according to the requirements of the corresponding subsystem in order to maintain reliable operation of the subsystem being provided with the output clock 160 during the supply voltage droop.

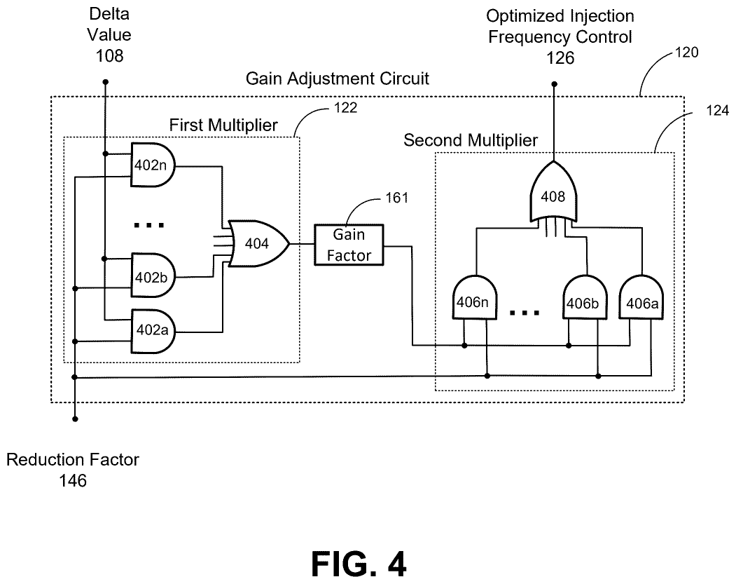

FIG. 4 is a schematic diagram showing additional details of the gain adjustment circuit 120 of the phase-locked loop 100 shown in FIG. 1 according to an example implementation. In this example implementation, the reduction factor 146 is a function of 2^{x} where x is selected from a set of integers that determine a set of corresponding reductions of the target frequency 162 of the output clock 160. The reduction factor 146 as a function of 2^{x} has the property called the ‘one hot encoding characteristic’ such that only one bit is high at any time. The first multiplier 122 and the second multiplier 124 take advantage of this property of the reduction factor 146 with the following simplified structures operating as bit shifters that eliminate the need for more complex multiplier circuits, with higher speed and greater simplicity. The first multiplier 122 includes a plurality of NAND gates 402a, 402b, . . . 402n, each of the NAND gates 402a, 402b, ... 402n coupled to receive the delta value 108 and the reduction factor 146, and a OR gate with coupled to receive the output of each of the NAND gates 402a, 402b, . . . 402n. The second multiplier 124 includes a plurality of NAND gates 406a, 406b, . . . 406n, each of the NAND gates 406a, 406b, . . . 406n coupled to receive the delta value 108 and the reduction factor 146, and a OR gate with coupled to receive the output of each of the NAND gates 402a, 402b, . . . 402n.

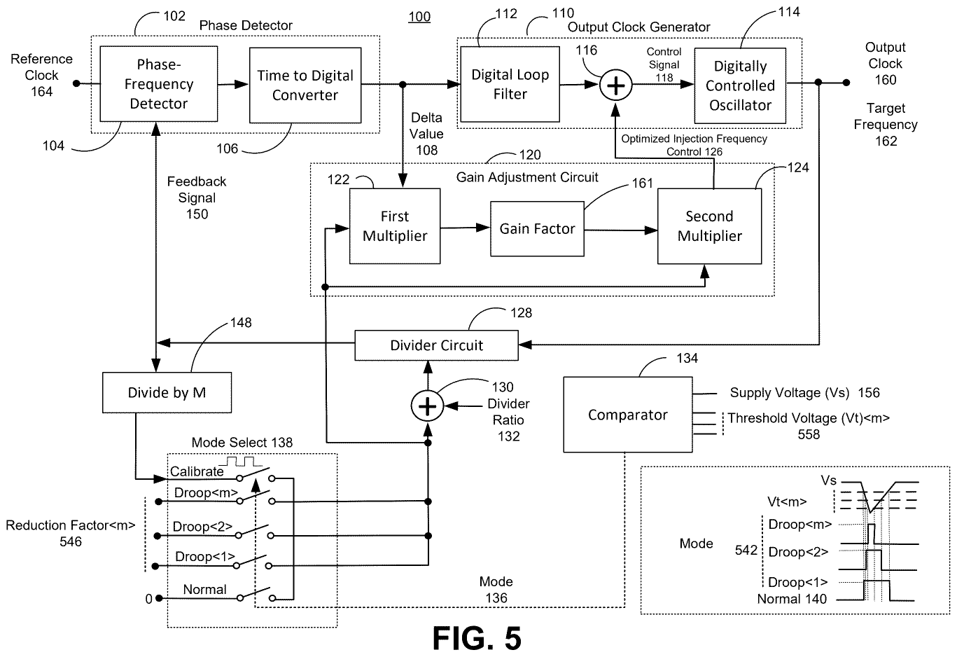

FIG. 5 is a schematic diagram of the phase-locked loop of FIG. 1 further including a multiple droop mode capability. All other elements of FIG. 5 are the same as those in FIG. 1 and, for the sake of brevity, will not be described further. The comparator 134 is coupled to receive the supply voltage 156 and a first set of threshold voltages 558. The comparator 134 operates to compare the supply voltage 156 to the first set of threshold voltages 558 to produce the mode 136 that includes a second set of droop modes 542. When the supply voltage 156 is greater than the first set of threshold voltages 558, the comparator 134 signals the state of the mode 136 to be the normal mode 140. When the supply voltage 156 is less than a threshold voltage 558, the comparator 134 determines the state of the mode 136 to be a droop mode 542 from the second set of droop modes corresponding to the threshold voltage 558 from the first set of threshold voltages 558. The mode select block 138 is coupled to receive the mode 136 from the comparator 134 and selectively provides a reduction factor 546 from a third set of reduction factors 546, the reduction factor 546 corresponding to the droop mode 542 from the second set of droop modes 542. The third set of reduction factors 546 would include selectively larger values to inject into the adder 130, resulting in selectively larger deductions from the divider ratio 132 which would further reduce the target frequency 162. The multiple droop mode capability described above provides the phase-locked loop 100 with the ability to adaptively provide a reduced frequency of the output clock 160 according to the requirements of the corresponding subsystem receiving the output clock 160 in order to maintain reliable operation during the supply voltage droop. For example, a more severe voltage droop would result in a further reduced frequency of the output clock 160.

The phase-locked loop of FIG. 1 further including a multiple droop mode capability as described in FIG. 5 may be implemented in combination with or independently of the frequency overshoot remover capability as described in FIG. 2. Both aspects illustrate the versatility of the phase-locked loop 100 to quickly and adaptively provide the reduced clock frequency according to the requirements of the corresponding subsystem receiving the output clock 160 in order to maintain reliable operation during the supply voltage droop.

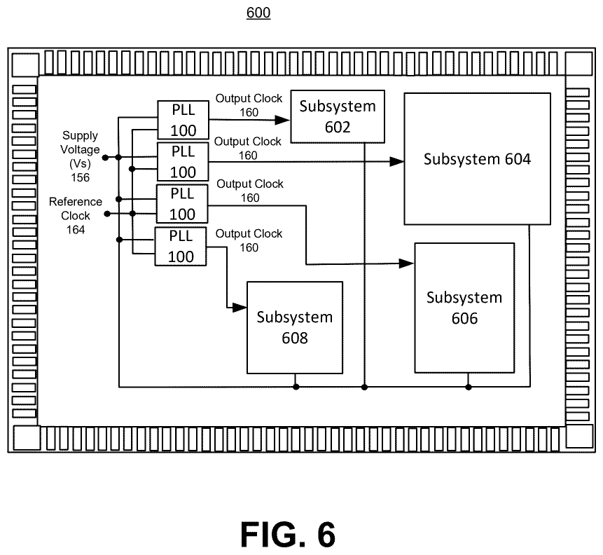

FIG. 6 is a block diagram of an exemplary integrated circuit implementation of the phase-locked loop 100. A plurality of phase-locked loops 100 are coupled to receive the supply voltage 156 and the reference clock 164 on a die of an integrated circuit 600. The phase-locked loops 100 each provide the output clock 160 to one of a corresponding subsystem 602, 604, 606, or 608 as commonly done in a clock distribution network. When a supply voltage droop occurs, the phase-locked loops 100 will provide the output clock 160 at a reduced frequency to the corresponding subsystems 602, 604, 606, and 608. The reduced clock frequency of the output clock 160 during a voltage droop may be different among the corresponding subsystems 602, 604, 606, and 608 and is chosen according to the requirements of the corresponding subsystem 602, 604, 606, or 608 with the reduction factor 146 selected accordingly in order to maintain reliable operation during the supply voltage droop. Similarly, the transition between the normal mode 140 and the droop mode 142 may be different among the corresponding subsystems 602, 604, 606, and 608 and is chosen according to the requirements of the corresponding subsystem 602, 604, 606, or 608 with the threshold voltage 158 selected accordingly in order to maintain reliable operation during the supply voltage droop. For example, the corresponding subsystem 604 implemented as an AI processor may be more sensitive to voltage droop than the corresponding subsystem 606 implemented as a memory core, such that the corresponding subsystem 604 would require a lower reduced frequency in order to maintain reliable operation.

The exemplary integrated circuit implementation of the phase-locked loop 100 shown in FIG. 6 as applied with the corresponding subsystems 602-608 fabricated on a single die, the invention could be advantageously applied in clock distribution networks that span multiple semiconductor dies or across 3 D (3 dimensional) packaging structures such as System-on-Chip, application specific integrated circuits (ASICs) and chiplets that are interconnected using redistribution layers (RDLs), fanout wafers, through-silicon vias (TSVs), solder microbumps, and related structures.

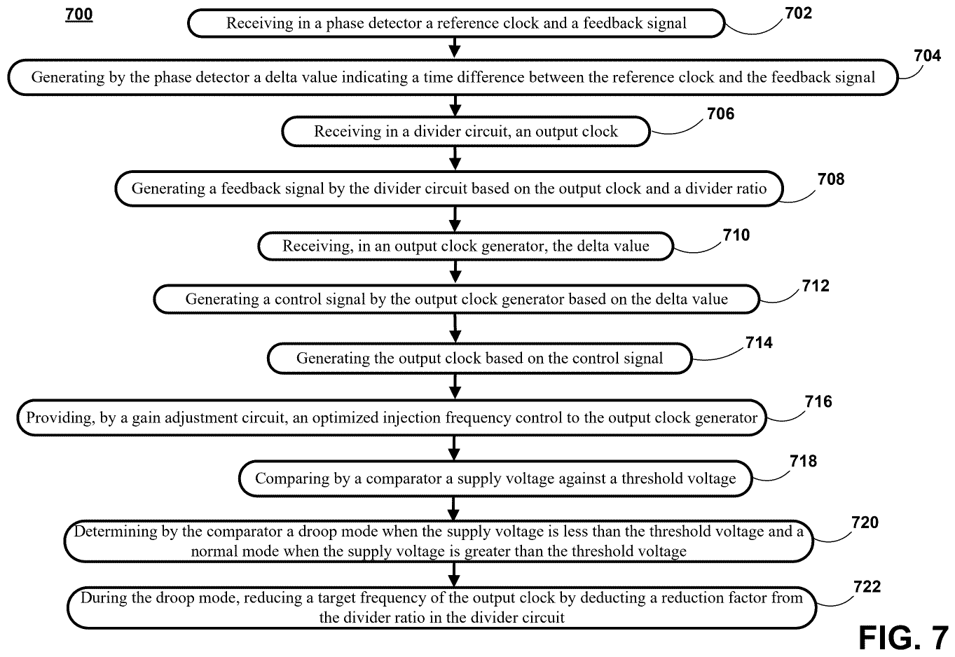

FIG. 7 is a flow chart of an example process 700 for generating an output clock 160 according to the techniques disclosed herein which can be implemented by the phase-locked loop 100 as discussed in the preceding examples.

The process 700 includes an operation 702 of receiving in a phase detector 102 a reference clock 164 and a feedback signal 150. The phase detector 102 coupled to receive the feedback signal 150 from a divider circuit 128. The reference clock 164 is received from an external source, such as a crystal-controlled oscillator that has a reference clock frequency that is relatively stable over temperature and voltage. The feedback signal 150 during normal operation will have a frequency the same as the frequency of the reference clock 164.

The process 700 includes an operation 704 of generating in the phase detector 102 a delta value 108 indicating a time difference between the reference clock 164 and the feedback signal 150. The delta value 108 is quantified digitally as a binary number generated by the phase detector 102. An output clock generator 110 is coupled to the phase detector 102 to receive the delta value 108. The output clock generator 110 generates an output clock 160 at a target frequency 162 responsive to the delta value 108.

The process 700 includes an operation 706 for receiving in a divider circuit 128 the output clock 160. The divider circuit 128 can be implemented using a ‘multi-modulus divider’ (MMD) or similar. The output clock generator 110 produces the output clock 160 at a target frequency 162.

The process 700 includes an operation 708 for generating the feedback signal 150 by the divider circuit 128 based on the output clock 160 and the divider ratio 132. The divider circuit 128 is coupled to an adder 130 to receive a divider ratio 132 that determines the target frequency 162. For example, the divider ratio set to 40 with a reference clock 164 at the reference frequency of 150 MHz would yield the target frequency 162 to be 6 GHz.

The process 700 includes an operation 710 for receiving, in the output clock generator 110 the delta value 108. The output clock generator 110 further includes a digital loop filter 112 coupled to receive the delta value 108.

The process 700 includes an operation 712 for generating a control signal 118 based on the delta value 108. An adder 116 is coupled to receive the output of the digital loop filter 112 as a filtered delta value and an optimized injection frequency control 126 from a gain adjustment circuit 120 to produce the control signal 118. The output clock generator 110 further includes a digitally controlled oscillator (DCO) 114 that is coupled to the adder 116 to receive the control signal 118

The process 700 includes an operation 714 for generating the output clock 160 based on the control signal 118. The output clock generator 110 includes a digitally controlled oscillator (DCO) 114 that is coupled to the adder 116 to receive the control signal 118 and generate the output clock 160 at the target frequency 162 based on the control signal 118.

The process 700 includes an operation 716 for providing, by the gain adjustment circuit 120, an optimized injection frequency control 126 to the output clock generator 110 which is received by the adder 116. The gain adjustment circuit 120 is coupled to the phase detector 102 to receive the delta value 108 and is further coupled to a mode select block 138 to receive an error value that is one of a ‘0’ during a normal mode 140 corresponding to no injection into the adder 130, a reduction factor 146 during a droop mode 142, and a low-frequency calibrate signal 145 during a calibration mode 144. The gain adjustment circuit 120 further includes a first multiplier 122 and a second multiplier 124, the first multiplier 122 coupled to the second multiplier 124 via a gain factor block 161, and the first multiplier 122 and the second multiplier 124 both coupled to receive the error value from the mode select block 138. During a calibration mode 144, which may be externally selected at desired intervals, a divide-by-M block 148 is activated to produce the low-frequency calibrate signal 145. The gain factor block 161 that stores a gain factor that is used in conjunction with the first multiplier 122 and the second multiplier 124 to obtain the optimized injection frequency control 126 to adjust the gain of the output clock generator 110 to a nominal value that provides a desired loop bandwidth of the phase-locked loop 100.

The process 700 includes an operation 718 for comparing by a comparator 134 a supply voltage 156 to a threshold voltage 158 to produce the mode 136. Alternatively, the comparator 134 is coupled to receive the supply voltage 156 and a first set of threshold voltages 558. The comparator 134 operates to compare the supply voltage 156 to the first set of threshold voltages 558 to determine the mode 136 that includes a second set of droop modes 542. The process 700 includes an operation 720 for determining by the comparator 134 a droop mode 142 and a normal mode 140. When the supply voltage 156 is greater than the threshold voltage 158, the comparator 134 determines the state of the mode 136 to be the normal mode 140. When the supply voltage 156 is less than the threshold voltage 158, the comparator 134 determines the state of the mode 136 to be the droop mode 142. The change in state of the mode 136 between the normal mode 140 and the droop mode 142 are the transitions.

The process 700 includes an operation 722, during droop mode 142 for reducing the target frequency 162 of the output clock 160 by deducting a reduction factor 146 from the divider ratio 132 in the divider circuit 128. The reduction factor 146 is chosen to provide the output clock 160 with a reduced frequency of the output clock 160 according to the requirements of the corresponding subsystem being provided with the output clock 160 in order to maintain reliable operation of the corresponding subsystem during the supply voltage droop. In this example, with a divider ratio 132 of 40 and the reference clock 164 with a reference frequency of 150 MHz, and a reduction factor of 2, the target frequency 162 transitions from 6 Ghz during the normal mode 140 to 5.7 GHz during the droop mode 142.

While various embodiments have been described, the description is intended to be exemplary, rather than limiting, and it is understood that many more embodiments and implementations are possible that are within the scope of the embodiments. Although many possible combinations of features are shown in the accompanying figures and discussed in this detailed description, many other combinations of the disclosed features are possible. Any feature of any embodiment may be used in combination with or substituted for any other feature or element in any other embodiment unless specifically restricted. Therefore, it will be understood that any of the features shown and/or discussed in the present disclosure may be implemented together in any suitable combination. Accordingly, the embodiments are not to be restricted except in light of the attached claims and their equivalents. Also, various modifications and changes may be made within the scope of the attached claims.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element. Furthermore, subsequent limitations referring back to “said element” or “the element” performing certain functions signifies that “said element” or “the element” alone or in combination with additional identical elements in the process, method, article or apparatus are capable of performing all of the recited functions.

The disclosure provides many different embodiments, or examples, for implementing different features of the provided subject matter. Specific examples of components and arrangements are described to simplify the present disclosure. These are merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claims require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A phase-locked loop, comprising:
a phase detector that receives a reference clock and a feedback signal, the phase detector generating a delta value indicating a time difference between the reference clock and the feedback signal;
an output clock generator that receives the delta value, generates a control signal based on the delta value, and generates an output clock at a target frequency based on the control signal;
a divider circuit that receives the output clock and generates the feedback signal based on the output clock and a divider ratio;
a gain adjustment circuit that provides an optimized injection frequency control to the control signal of the output clock generator; and
a comparator that compares a supply voltage against a threshold voltage to determine a mode including a droop mode when the supply voltage is less than the threshold voltage and a normal mode when the supply voltage is greater than the threshold voltage, wherein during the droop mode, a reduction factor is deducted from the divider ratio that reduces the target frequency of the output clock.

2. The phase-locked loop of claim 1, further comprising a frequency overshoot remover coupled to the comparator and to the divider circuit, wherein the frequency overshoot remover delays deducting the reduction factor from the divider ratio in the divider circuit during a transition from the droop mode to the normal mode.

3. The phase-locked loop of claim 1, wherein the output clock generator further includes:
a digital loop filter coupled to the phase detector to receive the delta value and provide a filtered delta value;
an adder coupled to the digital loop filter and the gain adjustment circuit to produce the control signal; and
a digitally controlled oscillator coupled to the adder to receive the control signal and generate the output clock at the target frequency.

4. The phase-locked loop of claim 1, the phase detector further comprising:
a phase-frequency detector for receiving the reference clock and the feedback signal; and
a time-to-digital converter coupled to the phase-frequency detector to generate the delta value.

5. The phase-locked loop of claim 1, the gain adjustment circuit further comprising:
a first multiplier coupled to receive the reduction factor;
a gain factor block coupled to the first multiplier; and
a second multiplier coupled to the gain factor block to provide the optimized injection frequency control.

6. The phase-locked loop of claim 1, further comprising a mode select block coupled to the comparator to receive the mode, wherein during the droop mode, the mode select block provides the reduction factor to the gain adjustment circuit to adjust the optimized injection frequency control and to the divider circuit to deduct the reduction factor from the divider ratio.

7. The phase-locked loop of claim 6, wherein the mode further comprises a calibration mode.

8. The phase-locked loop of claim 7, further comprising a divide-by-M block coupled to the mode select block, wherein during the calibration mode, the divide-by-M block provides a low-frequency calibrate signal to the divider circuit to calibrate a gain factor block.

9. The phase-locked loop of claim 1, wherein the reduction factor is a function of 2^{x} where x is selected from a set of integers that determine a set of corresponding reductions of the target frequency of the output clock.

10. The phase-locked loop of claim 9, wherein a first multiplier and a second multiplier comprise a bit shifter implemented using a plurality of NAND gates.

11. The phase-locked loop of claim 1 further comprising:
a first set of threshold voltages;
a second set of droop modes corresponding to the first set of threshold voltages; and
a third set of reduction factors corresponding to the second set of droop modes, wherein the comparator compares the supply voltage against the first set of threshold voltages and determines the droop mode from the second set of droop modes when the supply voltage is less than the threshold voltage of the first set of threshold voltages.

12. A method of generating an output clock in a phase-locked loop, comprising:
receiving in a phase detector a reference clock and a feedback signal;
generating by the phase detector a delta value indicating a time difference between the reference clock and the feedback signal;
receiving in a divider circuit the output clock;
generating a feedback signal by the divider circuit based on the output clock and a divider ratio;
receiving, in an output clock generator, the delta value;
generating a control signal by the output clock generator based on the delta value;
generating the output clock based on the control signal;
providing, by a gain adjustment circuit, an optimized injection frequency control to the output clock generator;
comparing by a comparator a supply voltage against a threshold voltage;
determining by the comparator a droop mode when the supply voltage is less than the threshold voltage and a normal mode when the supply voltage is greater than the threshold voltage; and
during the droop mode, reducing a target frequency of the output clock by deducting a reduction factor from the divider ratio in the divider circuit.

13. The method of claim 12, further comprising inserting a frequency overshoot remover to delay deducting the reduction factor from the divider ratio in the divider circuit during a transition from the droop mode to the normal mode.

14. The method of claim 12, further comprising:
receiving a reduction factor by a first multiplier and a second multiplier in the gain adjustment circuit, the first multiplier coupled to the second multiplier through a gain factor block;
receiving a delta value by the first multiplier; and
producing by the second multiplier the optimized injection frequency control.

15. The method of claim 12, further comprising:
during a calibration mode, providing by a divide-by-M block a low-frequency calibrate signal to the divider circuit; and
calibrating a gain factor block according to the low-frequency calibrate signal.

16. The method of claim 12, further comprising:
comparing by the comparator the supply voltage against a first set of threshold voltages;
determining the droop mode from a second set of droop modes corresponding to the first set of threshold voltages; and
during the droop mode, reducing the target frequency of the output clock by deducting the reduction factor from a third set of reduction factors corresponding to the droop mode from the divider ratio in the divider circuit.

17. The method of claim 12, further comprising determining the reduction factor according to a function of 2^{x} where x is selected from a set of integers that determine a set of corresponding reductions of the target frequency of the output clock.

18. An integrated circuit, comprising:
a plurality of subsystems coupled to receive a supply voltage; and
a plurality of phase-locked loops, the plurality of phase-locked loops coupled to receive the supply voltage and a reference clock, and further coupled to a corresponding subsystem to provide an output clock to the corresponding subsystem, the plurality of phase-locked loops comprising:
a phase detector that receives the reference clock and a feedback signal, the phase detector generating a delta value indicating a time difference between the reference clock and the feedback signal;
a divider circuit that receives the output clock and generates the feedback signal based on the output clock and a divider ratio;
an output clock generator that receives the delta value, generates a control signal based on the delta value, and generates the output clock at a target frequency based on the control signal;
a gain adjustment circuit that provides an optimized injection frequency control to the output clock generator; and
a comparator that compares the supply voltage against a threshold voltage and determines a droop mode when the supply voltage is less than the threshold voltage and a normal mode when the supply voltage is greater than the threshold voltage;
wherein during the droop mode, a reduction factor is deducted from the divider ratio to reduce the target frequency of the output clock.

19. An integrated circuit of claim 18, wherein the threshold voltage is determined according to the corresponding subsystem to maintain reliable operation of the corresponding subsystem during the droop mode.

20. An integrated circuit of claim 18, wherein the reduction factor is determined according to the corresponding subsystem by reducing the target frequency to maintain reliable operation of the corresponding subsystem during the droop mode.
